(19) United States
(12) Patent Application Publication
(10) Pub. No.: US 2024/0290738 A1
(43) Pub. Date: Aug. 29, 2024

(54) SEMICONDUCTOR DEVICE

(71) Applicant: SAMSUNG ELECTRONICS CO., LTD., Suwon-si (KR)

(72) Inventors: Bongwee Yu, Suwon-si (KR); Junho Huh, Suwon-si (KR)

(21) Appl. No.: 18/510,967

(22) Filed: Nov. 16, 2023

(30) Foreign Application Priority Data
Feb. 28, 2023 (KR) 10-2023-0026803

(51) Int. Cl. H01L 23/00; H01L 23/48; H01L 23/522

(52) U.S. Cl. CPC H01L 24/06; H01L 23/481; H01L 23/5226; H01L 24/16; H01L 2224/061; H01L 2224/16145; H01L 2224/16227

(57) ABSTRACT

A semiconductor device includes a first die having a first and second physical layer regions adjacent each other, connecting pads and a connecting wire on a lower surface of the first die, a rear wiring layer having a first rear wire on the first die, and through silicon vias penetrating the first die, the through silicon vias including a first and second through silicon vias. The connecting pads include a first and a second connecting pads electrically connected with the first and second physical layer regions respectively, and a first and a second pads electrically connected with the first and second through silicon vias respectively. The first rear wire is electrically connected with the first and second through silicon vias. The connecting wire is electrically connected with the first connecting pad and the first pad.

### CROSS-REFERENCE TO RELATED APPLICATIONS

This application claims priority under 35 U.S.C. § 119 to Korean Patent Application No. 10-2023-0026803 filed on Feb. 28, 2023, in the Korean Intellectual Property Office, the disclosures of which are incorporated by reference herein in their entireties.

### BACKGROUND

### 1. Field

Embodiments of the present disclosure described herein relate to a semiconductor device, and more particularly, relate to a semiconductor device including a 3D integrated circuit (3DIC) on a package substrate.

### 2. Description of the Related Art

A system in package (SIP), in which multiple semiconductor elements are equipped in a single package, is being developed. In order to reduce the areas occupied by the semiconductor elements in the package and to implement high-speed communication between the semiconductor elements, a three-dimensional semiconductor device in which multiple semiconductor elements are vertically stacked using through silicon vias (TSVs) needs to be developed.

### SUMMARY

Embodiments are directed to a semiconductor device that may have a first die including a first physical layer region and a second physical layer region adjacent to each other, connecting pads on a lower surface of the first die, a connecting wire on the lower surface of the first die, a rear wiring layer on the first die. The rear wiring layer may include a first rear wire, and through silicon vias configured to penetrate the first die. The through silicon vias may include a first through silicon via and a second through silicon via. The connecting pads may include a first connecting pad that may be electrically connected with the first physical layer region, a second connecting pad that may be electrically connected with the second physical layer region, a first pad that may be electrically connected with the first through silicon via, and a second pad that may be electrically connected with the second through silicon via. The first rear wire may be electrically connected with the first through silicon via and the second through silicon via. The connecting wire may be electrically connected with the first connecting pad and the first pad.

According to an embodiment, a semiconductor device may include a first die having a first physical layer region and a second physical layer region, and silicon vias configured to penetrate the first die. The through silicon vias may include a first through silicon via and a second through silicon via. The first physical layer region may be adjacent to a first side surface of the first die, and the second physical layer region may be adjacent to a second side surface configured to face away from the first side surface. The semiconductor device may further include connecting pads on a lower surface of the first die, the connecting pads may include a first connecting pad that may be electrically connected with the first physical layer region, a second connecting pad that may be electrically connected with the second physical layer region, a first pad that may be electrically connected with the first through silicon via, a second pad that may be electrically connected with the second through silicon via, and a connecting wire on the lower surface of the first die, the connecting wire may be electrically connected with the first connecting pad and the first pad. A rear wiring layer may be provided on the first die, the rear wiring layer may include a second rear wire, the second rear wire may be electrically connected with the first through silicon via and the second through silicon via.

According to an embodiment, a semiconductor device may include a first die having a first power domain and a second power domain adjacent to each other, and electronic elements that may be configured to operate at a same power voltage provided in the first power domain and the second power domain. The first die may include through silicon vias configured to penetrate the first die, the through silicon vias may include a first through silicon via and a second through silicon via. Connecting pads on a lower surface of the first die may include a first connecting pad that may be electrically connected with the first power domain, a second connecting pad that may be electrically connected with the second power domain, a first pad that may be electrically connected with the first through silicon via, and a second pad that may be electrically connected with the second through silicon via. The semiconductor device may further include a connecting wire on the lower surface of the first die, the connecting wire may be electrically connected with the second connecting pad and the first pad, and a rear wiring layer on the first die, the rear wiring layer may include a third rear wire that may be electrically connected with the first through silicon via and the second through silicon via. Embodiments of the present disclosure provide a semiconductor device having improved electrical characteristics.

### BRIEF DESCRIPTION OF THE FIGURES

Features will become apparent to those of skill in the art by describing in detail exemplary embodiments with reference to the attached drawings, in which:

FIG. 1 is a cross-sectional view showing an example of a semiconductor device;

FIG. 2 is a cross-sectional view showing an example of a semiconductor device;

FIG. 3 is a cross-sectional view showing a semiconductor device according to an embodiment of the present disclosure;

FIG. 4 is an enlarged view of region M shown in FIG. 3 according to an embodiment;

FIG. 5 is an enlarged view of region M shown in FIG. 3 according to an embodiment;

FIG. 6 is a plan view showing a lower surface of a first die shown in FIG. 3;

FIG. 7 is a plan view showing the semiconductor device of FIG. 3 as viewed from above;

FIG. 8 is a cross-sectional view showing an example of a semiconductor package including the semiconductor device shown in FIG. 3;

FIG. 9 is a cross-sectional view showing an example of a semiconductor package including the semiconductor device shown in FIG. 3;

FIG. 10 is a cross-sectional view showing a semiconductor device according to an embodiment of the present disclosure;

FIG. 11 is a plan view showing a lower surface of a first die shown in FIG. 10;

FIG. 12 is a plan view showing the semiconductor device shown in FIG. 10 as viewed from above;

FIG. 13 is a cross-sectional view showing an example of a semiconductor package including the semiconductor device shown in FIG. 10;

FIG. 14 is a cross-sectional view showing an example of a semiconductor package including the semiconductor device shown in FIG. 10;

FIG. 15 is a plan view showing a semiconductor device;

FIG. 16 is a cross-sectional view taken along line I-I′ of FIG. 15;

FIG. 17 is a plan view showing a semiconductor device according to an embodiment of the present disclosure; and

FIG. 18 is a cross-sectional view taken along line II-II′ of FIG. 17.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

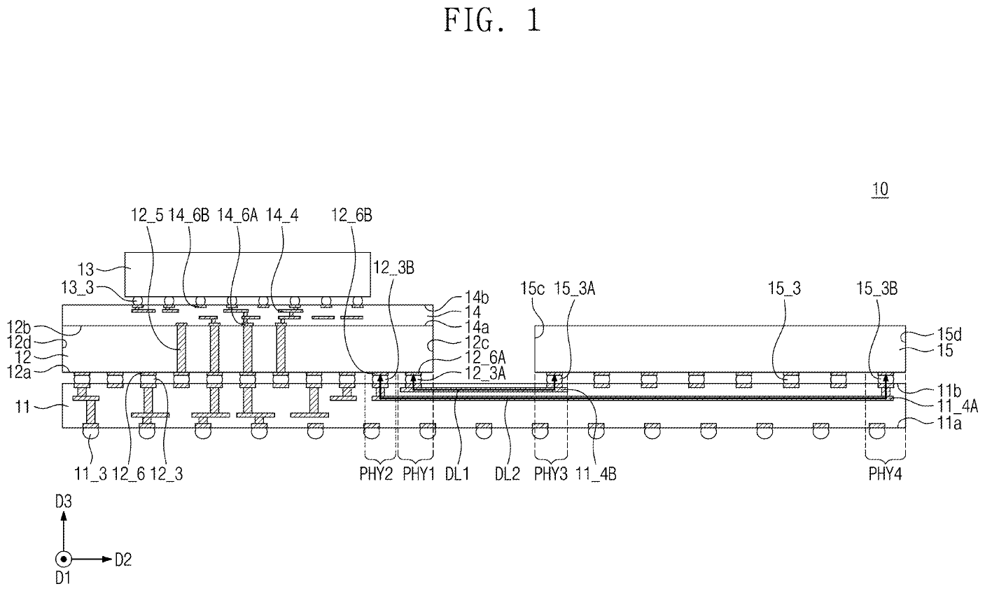

FIG. 1 is a cross-sectional view showing an example of a semiconductor device.

Referring to FIG. 1, the semiconductor device 10 may include a package substrate 11, a first die 12, a rear wiring layer 14, a second die 13, and a memory die 15. For example, the memory die 15 may be horizontally positioned side by side with the first die 12 on the package substrate 11.

The package substrate 11 may have a lower surface 11a parallel to a first direction D1 and a second direction D2 and an upper surface 11b facing away from the lower surface 11a. The first direction D1 and the second direction D2 may be perpendicular to each other. Solder balls 11_3 may be provided on the lower surface 11a of the package substrate 11.

The first die 12 may be provided on the upper surface 11b of the package substrate 11. The first die 12 may be a processor chip. For example, the first die 12 may include a central processing unit (CPU), a physical layer interface (PHY), and a memory controller (MCT).

The first die 12 may have a lower surface 12a and an upper surface 12b facing away from the lower surface 12a, a first side surface 12c and a second side surface 12d. The lower surface 12a of the first die 12 may face toward the package substrate 11.

Connecting pads 12_6 and connecting terminals 12_3 may be provided on the lower surface 12a of the first die 12. The connecting terminals 12_3 may be provided between the first die 12 and the package substrate 11. The connecting pads 12_6 may be provided between the connecting terminals 12_3 and the first die 12. The first die 12 may be electrically connected with the package substrate 11 through the connecting pads 12_6 and the connecting terminals 12_3.

The first die 12 may include a plurality of through silicon vias (TSVs) 12_5. The through silicon vias 12_5 may penetrate the first die 12. In other words, the through silicon vias 12_5 may extend from the lower surface 12a to the upper surface 12b of the first die 12 in a third direction D3 perpendicular to the lower surface 12a of the first die 12. The through silicon vias 12_5 may be electrically connected with some of the connecting pads 12_6.

The rear wiring layer 14 may be provided on the upper surface 12b of the first die 12. The rear wiring layer 14 may include first rear pads 14_6A, second rear pads 14_6B, and rear wires 14_4.

The first rear pads 14_6A may be provided on a lower surface 14a of the rear wiring layer 14. The first rear pads 14_6A may be connected with the through silicon vias 12_5 on the upper surface 12b of the first die 12, respectively. The second rear pads 14_6B may be provided on an upper surface 14b of the rear wiring layer 14. For example, the second rear pads 14_6B may be exposed on the upper surface 14b of the rear wiring layer 14. The first rear pads 14_6A and the second rear pads 14_6B may be electrically connected through the rear wires 14_4.

The second die 13 may be provided on the upper surface 14b of the rear wiring layer 14. The second die 13 may be a processor chip. For example, the second die 13 may include a central processing unit (CPU), a graphic processing unit (GPU), or a system on chip (SoC). For example, the second die 13 may be a semiconductor chip of the same type as, or a different type from, the first die 12.

Micro-bumps 13_3 may be provided between the second die 13 and the rear wiring layer 14. The micro-bumps 13_3 may be electrically connected with the second rear pads 14_6B. The second die 13 may be electrically connected with the package substrate 11 through the micro-bumps 13_3, the second rear pads 14_6B, the rear wires 14_4, the first rear pads 14_6A, the through silicon vias 12_5, the connecting pads 12_6, and the connecting terminals 12_3.

The memory die 15 may be provided on the package substrate 11. The memory die 15 may include a memory chip. For example, the memory chip may include DRAM, SRAM, MRAM, and/or NAND flash memory.

The memory die 15 may be spaced apart from the first die 12 on the upper surface 11b of the package substrate 11. For example, the memory die 15 may be spaced apart from a first side surface 12c of the first die 12 in the second direction D2.

Memory connecting terminals 15_3 may be provided on a lower surface 15a of the memory die 15. The memory connecting terminals 15_3 may be provided between the memory die 15 and the package substrate 11. The memory die 15 may be electrically connected with the package substrate 11 through the memory connecting terminals 15_3.

The first die 12 may include a first physical layer region PHY1 and a second physical layer region PHY2. A physical layer interface for connection to the first die 12 may be provided in the first physical layer region PHY1 and the second physical layer region PHY2 of the first die 12.

The first physical layer region PHY1 and the second physical layer region PHY2 may be adjacent to each other. The expression “A is adjacent to B” used herein may mean that a component performing substantially the same operation or function as A or B is not between A and B. The expression “A is adjacent to side surface C of B” used herein may mean that A is closest to side surface C among side surfaces of B.

For example, the first physical layer region PHY1 may be adjacent to the first side surface 12c adjacent to the memory die 15. For example, the second physical layer region PHY2 may be adjacent to the first physical layer region PHY1. For example, the first physical layer region PHY1 may be provided between the second physical layer region PHY2 and the first side surface 12c.

The memory die 15 may include a third physical layer region PHY3 and a fourth physical layer region PHY4. A physical layer interface for connection to the memory die 15 may be provided in the third physical layer region PHY3 and the fourth physical layer region PHY4 of the memory die 15.

The third physical layer region PHY3 may be adjacent to a first side surface 15c of the memory die 15, and the fourth physical layer region PHY4 may be adjacent to a second side surface 15d of the memory die 15. The first side surface 15c and the second side surface 15d of the memory die 15 may face away from each other. For example, the first side surface 15c of the memory die 15 may face the first side surface 12c of the first die 12. In other words, the first side surface 15c of the memory die 15 may be adjacent to the first side surface 12c of the first die 12.

A first data line DL1 may be provided between the first physical layer region PHY1 and the third physical layer region PHY3. A second data line DL2 may be provided between the second physical layer region PHY2 and the fourth physical layer region PHY4. Data may be exchanged between the first die 12 and the memory die 15 through the first data line DL1 and the second data line DL2.

Specifically, the connecting pads 12_6 may include a first connecting pad 12_6A electrically connected with the first physical layer region PHY1 of the first die 12 and a second connecting pad 12_6B electrically connected with the second physical layer region PHY2 of the first die 12.

The connecting terminals 12_3 may include a first connecting terminal 12_3A electrically connected with the first connecting pad 12_6A and a second connecting terminal 12_3B electrically connected with the second connecting pad 12_6B.

The memory connecting terminals 15_3 may include a first memory connecting terminal 15_3A electrically connected with the third physical layer region PHY3 of the memory die 15 and a second memory connecting terminal 15_3B electrically connected with the fourth physical layer region PHY4 of the memory die 15.

The package substrate 11 may have a plurality of conductive lines including a first conductive line 11_4A and a second conductive line 11_4B. The first connecting terminal 12_3A and the first memory connecting terminal 15_3A may be electrically connected through the first conductive line 11_4A. The second connecting terminal 12_3B and the second memory connecting terminal 15_3B may be electrically connected through the second conductive line 11_4B.

The first connecting pad 12_6A, the first connecting terminal 12_3A, the first conductive line 11_4A, and the first memory connecting terminal 15_3A may constitute the first data line DL1. The first physical layer region PHY1 and the third physical layer region PHY3 may be electrically connected through the first data line DL1.

The second connecting pad 12_6B, the second connecting terminal 12_3B, the second conductive line 11_4B, and the second memory connecting terminal 15_3B may constitute the second data line DL2. The second physical layer region PHY2 and the fourth physical layer region PHY4 may be electrically connected through the second data line DL2.

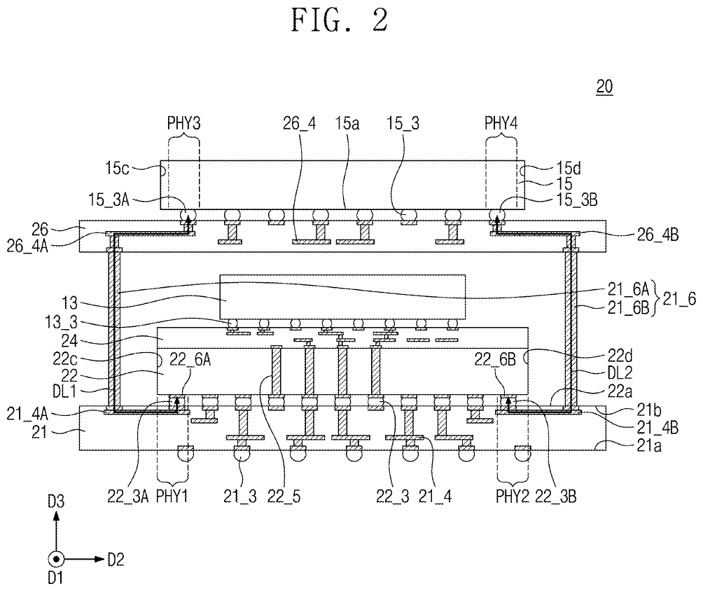

FIG. 2 is a view showing an example of a semiconductor device. Hereinafter, descriptions of components substantially the same as those described with reference to FIG. 1 will be omitted, and the following description will be focused on a difference.

Referring to FIG. 2, the semiconductor device 20 may include a package substrate 21 having a lower surface 21a and an upper surface 21b, a first die 22, a rear wiring layer 24, a second die 13, an upper wiring layer 26, and a memory die 15. The semiconductor device 20 may be a semiconductor device manufactured in a package-on-package (POP) form. Solder balls 21_3 may be provided on the lower surface 21a of the package substrate 21.

The first die 22 may be mounted on an upper surface 21b of the package substrate 21. Connecting pads 22_6A, 22_6B and connecting terminals 22_3 may be provided on the lower surface 22a of the first die 22. The first die 22 may be electrically connected with the package substrate 21 through the connecting pads 22_6A, 22_6B and the connecting terminals 22_3.

The first die 22 may include a plurality of through silicon vias (TSVs) 22_5.

The rear wiring layer 24 may be provided on an upper surface of the first die 22. The rear wiring layer 24 may be substantially the same as the rear wiring layer 14 in FIG. 1.

The second die 13 may be provided on an upper surface of the rear wiring layer 24. The second die 13 may be substantially the same as the second die 13 in FIG. 1.

Micro-bumps 13_3 may be provided between the second die 13 and the rear wiring layer 24. The second die 13 may be electrically connected with the package substrate 21 through the micro-bumps 13_3, the rear wiring layer 24, the through silicon vias 22_5, the connecting pads 22_6A, 22_6B, and the connecting terminals 22_3.

The upper wiring layer 26 may be provided over the second die 13. Although not illustrated in FIG. 2, a molding film configured to cover the first die 22 and the second die 13 may be provided on the upper surface 21b of the package substrate 21, and the upper wiring layer 26 may be provided on the molding film.

The upper wiring layer 26 may include upper wires 26_4. The upper wires 26_4 may include a first upper wire 26_4A and a second upper wire 26_4B.

Conductive fillers 21_6 may be provided between the upper wiring layer 26 and the package substrate 21. The conductive fillers 21_6 may include a first conductive filler 21_6A and a second conductive filler 21_6B.

The conductive fillers 21_6 may be spaced apart from the first die 22. For example, the first conductive filler 21_6A may be spaced apart from a first side surface 22c of the first die 22 so as to be adjacent to the first side surface 22c, and the second conductive filler 21_6B may be spaced apart from a second side surface 22d of the first die 22 so as to be adjacent to the second side surface 22d. The first side surface 22c and the second side surface 22d of the first die 22 may face away from each other.

The upper wiring layer 26 and the package substrate 21 may be electrically connected through the conductive fillers 21_6. For example, the first conductive filler 21_6A may be electrically connected with the first upper wire 26_4A, and the second conductive filler 21_6B may be electrically connected with the second upper wire 26_4B.

The memory die 15 may be provided on the upper wiring layer 26. Memory connecting terminals 15_3 may be provided on a lower surface 15a of the memory die 15. The memory connecting terminals 15_3 may be provided between the memory die 15 and the upper wiring layer 26. The memory die 15 may be electrically connected with the upper wiring layer 26 through the memory connecting terminals 15_3.

The first die 22 may include a first physical layer region PHY1 and a second physical layer region PHY2. A physical layer interface for connection to the first die 22 may be provided in the first physical layer region PHY1 and the second physical layer region PHY2 of the first die 22.

The first physical layer region PHY1 may be adjacent to the first side surface 22c of the first die 22, and the second physical layer region PHY2 may be adjacent to the second side surface 22d of the first die 22.

The memory die 15 may include a third physical layer region PHY3 and a fourth physical layer region PHY4. A physical layer interface for connection to the memory die 15 may be provided in the third physical layer region PHY3 and the fourth physical layer region PHY4 of the memory die 15.

The third physical layer region PHY3 may be adjacent to a first side surface 15c of the memory die 15, and the fourth physical layer region PHY4 may be adjacent to a second side surface 15d of the memory die 15. The first side surface 15c and the second side surface 15d of the memory die 15 may face away from each other.

A first data line DL1 may be provided between the first physical layer region PHY1 and the third physical layer region PHY3. A second data line DL2 may be provided between the second physical layer region PHY2 and the fourth physical layer region PHY4. Data may be exchanged between the first die 22 and the memory die 15 through the first data line DL1 and the second data line DL2.

Specifically, the connecting pads may include a first connecting pad 22_6A electrically connected with the first physical layer region PHY1 of the first die 22 and a second connecting pad 22_6B electrically connected with the second physical layer region PHY2 of the first die 22.

The connecting terminals 22_3 may include a first connecting terminal 22_3A electrically connected with the first connecting pad 22_6A and a second connecting terminal 22_3B electrically connected with the second connecting pad 22_6B.

The memory connecting terminals 15_3 may include a first memory connecting terminal 15_3A electrically connected with the third physical layer region PHY3 of the memory die 15 and a second memory connecting terminal 15_3B electrically connected with the fourth physical layer region PHY4 of the memory die 15.

The first memory connecting terminal 15_3A may be electrically connected with the first upper wire 26_4A. The second memory connecting terminal 15_3B may be electrically connected with the second upper wire 26_4B.

The package substrate 21 may include a plurality of conductive lines 21_4. The conductive lines 21_4 may include a first conductive line 21_4A electrically connected with the first connecting terminal 22_3A and the first conductive filler 21_6A and a second conductive line 21_4B electrically connected with the second connecting terminal 22_3B and the second conductive filler 21_6B.

The first connecting pad 22_6A and the first memory connecting terminal 15_3A may be electrically connected through the first connecting terminal 22_3A, the first conductive line 21_4A, the first conductive filler 21_6A, and the first upper wire 26_4A. The second connecting pad 22_6B and the second memory connecting terminal 15_3B may be electrically connected through the second connecting terminal 22_3B, the second conductive line 21_4B, the second conductive filler 21_6B, and the second upper wire 26_4B.

The first connecting pad 22_6A, the first connecting terminal 22_3A, the first conductive line 21_4A, the first conductive filler 21_6A, the first upper wire 26_4A, and the first memory connecting terminal 15_3A may constitute the first data line DL1. The first physical layer region PHY1 and the third physical layer region PHY3 may be electrically connected through the first data line DL1.

The second connecting pad 22_6B, the second connecting terminal 22_3B, the second conductive line 21_4B, the second conductive filler 21_6B, the second upper wire 26_4B, and the second memory connecting terminal 15_3B may constitute the second data line DL2. The second physical layer region PHY2 and the fourth physical layer region PHY4 may be electrically connected through the second data line DL2.

Unlike in FIG. 1, the first physical layer region PHY1 and the second physical layer region PHY2 of the first die 22 in the semiconductor device 20 of FIG. 2 are adjacent to the opposite side surfaces 22c and 22d of the first die 22. That is, unlike in the case in which the memory die 15 is side by side with the first die 12 as in FIG. 1, the positions of the first physical layer region PHY1 and the second physical layer region PHY2 of the first die 22 are changed in the case in which the memory die 15 and the first die 22 are vertically arranged in a package-on-package form as in FIG. 2. Accordingly, the first dies different from each other have to be manufactured based on the forms in which the memory dies 15 are arranged in semiconductor packages.

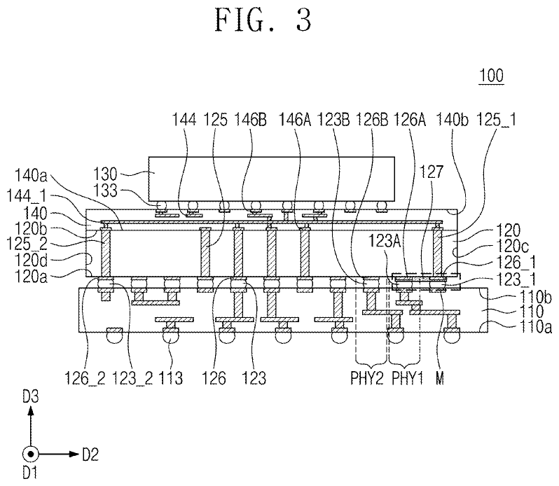

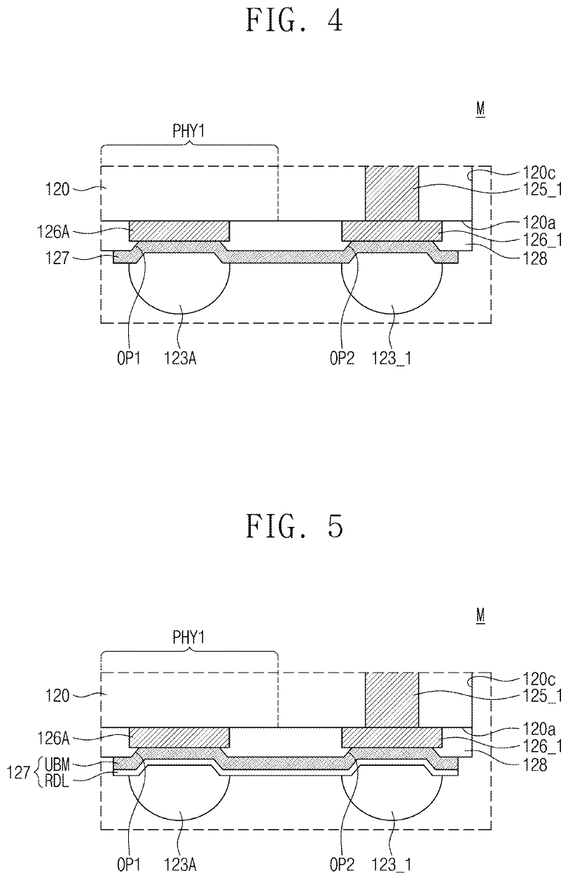

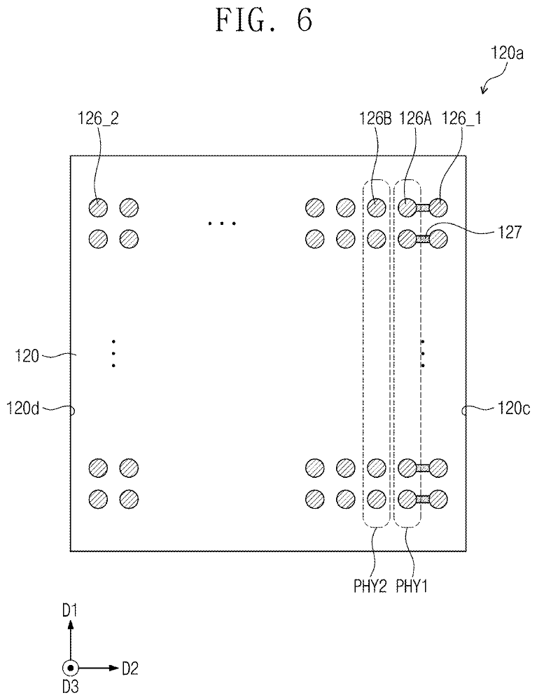

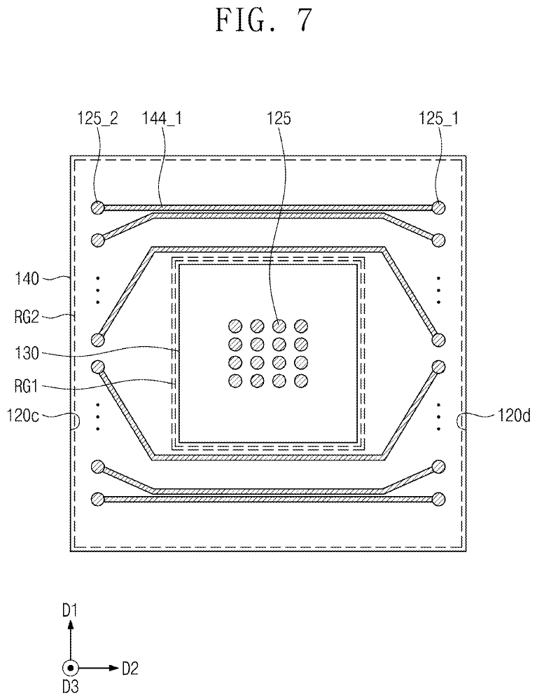

FIG. 3 is a view showing a semiconductor device according to an embodiment of the present disclosure. FIG. 4 is an enlarged view of region M in FIG. 3 according to an embodiment. FIG. 5 is an enlarged view of region M in FIG. 3 according to an embodiment. FIG. 6 is a view showing a lower surface of a first die of FIG. 3. FIG. 7 is a view showing the semiconductor device of FIG. 3 as viewed from above. Hereinafter, embodiments of the present disclosure will be described in detail with reference to FIGS. 3 to 7.

Referring to FIG. 3, the semiconductor device 100 may include a package substrate 110, the first die 120, a rear wiring layer 140, and a second die 130. For example, the semiconductor device 100 may be a 3D integrated circuit (3DIC).

The package substrate 110 may have a lower surface 110a parallel to the first direction D1 and the second direction D2 and an upper surface 110b facing away from the lower surface 110a. Solder balls 113 may be provided on the lower surface 110a of the package substrate 110.

The first die 120 may be provided on the upper surface 110b of the package substrate 110. The first die 120 may be a processor chip. For example, the first die 120 may include a central processing unit (CPU), a physical layer interface (PHY), and a memory controller (MCT).

The first die 120 may have the lower surface 120a and an upper surface 120b facing away from the lower surface 120a. The lower surface 120a of the first die 120 may face toward the package substrate 110.

Connecting pads 126 and connecting terminals 123 may be provided on the lower surface 120a of the first die 120. The connecting terminals 123 may be provided between the first die 120 and the package substrate 110. The connecting pads 126 may be provided between the connecting terminals 123 and the first die 120. The first die 120 may be electrically connected with the package substrate 110 through the connecting pads 126 and the connecting terminals 123.

The first die 120 may include a plurality of through silicon vias (TSVs) 125. The through silicon vias 125 may penetrate the first die 120. In other words, the through silicon vias 125 may extend from the lower surface 120a to the upper surface 120b of the first die 120 in the third direction D3 perpendicular to the lower surface 120a of the first die 120. The through silicon vias 125 may be electrically connected with some of the connecting pads 126.

The rear wiring layer 140 may be provided on the upper surface 120b of the first die 120. The rear wiring layer 140 may include first rear pads 146A, second rear pads 146B, and rear wires 144.

The first rear pads 146A may be provided on a lower surface 140a of the rear wiring layer 140. The first rear pads 146A may be connected with the through silicon vias 125 on the upper surface 120b of the first die 120, respectively. The second rear pads 146B may be provided on an upper surface 140b of the rear wiring layer 140. For example, the second rear pads 146B may be exposed on the upper surface 140b of the rear wiring layer 140. The first rear pads 146A and the second rear pads 146B may be electrically connected through the rear wires 144.

The second die 130 may be provided on the upper surface 140b of the rear wiring layer 140. The second die 130 may be a processor chip. For example, the second die 130 may include a central processing unit (CPU), a graphic processing unit (GPU), or a system on chip (SoC). For example, the second die 130 may be a semiconductor chip of the same type as, or a different type from, the first die 120.

Micro-bumps 133 may be provided between the second die 130 and the rear wiring layer 140. The micro-bumps 133 may be electrically connected with the second rear pads 146B. The second die 130 may be electrically connected with the package substrate 110 through the micro-bumps 133, the second rear pads 146B, the rear wires 144, the first rear pads 146A, the through silicon vias 125, the connecting pads 126, and the connecting terminals 123.

The first die 120 may include a first physical layer region PHY1 and a second physical layer region PHY2. A physical layer interface for connection to the first die 120 may be provided in the first physical layer region PHY1 and the second physical layer region PHY2 of the first die 120.

In an embodiment, the first physical layer region PHY1 and the second physical layer region PHY2 may be adjacent to each other. For example, the first physical layer region PHY1 may be provided between the second physical layer region PHY2 and a first side surface 120c of the first die 120.

The connecting pads 126 may include a first connecting pad 126A electrically connected with the first physical layer region PHY1 of the first die 120 and a second connecting pad 126B electrically connected with the second physical layer region PHY2 of the first die 120.

In an embodiment, the connecting pads 126 may include a first pad 126_1 and a second pad 126_2. For example, the first pad 126_1 may be adjacent to the first side surface 120c of the first die 120, and the second pad 126_2 may be adjacent to a second side surface 120d of the first die 120. For example, the first connecting pad 126A may be provided between the first pad 126_1 and the second connecting pad 126B.

The connecting terminals 123 may include a first connecting terminal 123A electrically connected with the first connecting pad 126A and a second connecting terminal 123B electrically connected with the second connecting pad 126B.

In an embodiment, the connecting terminals 123 may include a first terminal 123_1 electrically connected with the first pad 126_1 and a second terminal 123_2 electrically connected with the second pad 126_2.

In an embodiment, a first connecting wire 127 may be provided on the lower surface 120a of the first die 120. The first connecting wire 127 may be electrically connected with the first connecting pad 126A and the first pad 126_1. In other words, the first pad 126_1 and the first connecting pad 126A may be electrically connected through the first connecting wire 127.

Hereinafter, the first connecting wire 127 on the lower surface 120a of the first die 120 according to embodiments will be described in detail with reference to FIGS. 4 and 5.

Referring to FIG. 4 together, the first pad 126_1 may be provided on the lower surface 120a of the first die 120. For example, the first pad 126_1 may be a connecting pad adjacent to the first connecting pad 126A among the connecting pads 126. In another example, the first pad 126_1 may be a connecting pad electrically connected with the first connecting pad 126A among the connecting pads 126.

In an embodiment, the first pad 126_1 may be adjacent to the first side surface 120c of the first die 120. For example, the first pad 126_1 may be between the first connecting pad 126A and the first side surface 120c. However, without being limited to the illustrated embodiment, the position of the first pad 126_1 may be changed.

An insulating film 128 may be provided on the lower surface 120a of the first die 120. The insulating film 128 may be provided between the first connecting pad 126A and the first pad 126_1. The insulating film 128 may be configured to cover side surfaces of the first connecting pad 126A and the first pad 126_1.

The insulting film 128 may include a first opening OP1 and a second opening OP2. At least a portion of an upper surface of the first pad 126_1 may be exposed outside the insulating film 128 through the first opening OP1, and at least a portion of an upper surface of the first connecting pad 126A may be exposed outside the insulating film 128 through the second opening OP2.

The first connecting wire 127 may be provided on the first connecting pad 126A, the insulating film 128, and the first pad 126_1. For example, the first connecting wire 127 may extend on the insulating film 128 from the first connecting pad 126A in the first opening OP1 to the first pad 126_1 in the second opening OP2.

The first connecting wire 127 may be provided between the first connecting pad 126A and the first connecting terminal 123A. The first connecting wire 127 may also be provided between the first pad 126_1 and the first terminal 123_1. For example, the first connecting wire 127 may be commonly provided on the first connecting pad 126A and the first pad 126_1.

The first connecting pad 126A and the first pad 126_1 may be electrically connected through the first connecting wire 127. The first connecting terminal 123A and the first terminal 123_1 may also be electrically connected through the first connecting wire 127.

For example, the first connecting wire 127 may be an under bump metal (UBM).

Referring to FIG. 5 together, in an embodiment, unlike in FIG. 4, the first connecting wire 127 may further include a redistribution layer RDL. The redistribution layer RDL may be commonly provided between the under bump metal UBM and the first connecting terminal 123A and between the under bump metal UBM and the first terminal 123_1. The redistribution layer RDL may extend along the under bump metal UBM.

Referring to FIG. 6 together, the connecting pads 126 may include the first connecting pads 126A connected to the first physical layer region PHY1 and the second connecting pads 126B connected to the second physical layer region PHY2.

The first connecting pads 126A connected with the first physical layer region PHY1 may be arranged in the first direction D1. In an embodiment, the second connecting pads 126B connected with the second physical layer region PHY2 may be arranged in the first direction D1. For example, the first connecting pads 126A may be adjacent to the second connecting pads 126B in the second direction D2.

In an embodiment, the connecting pads 126 may include the first pads 126_1 and the second pads 126_2.

The first pads 126_1 may be arranged in the first direction D1. For example, the first pads 126_1 may be adjacent to the first side surface 120c of the first die 120. For example, the first pads 126_1 may be adjacent to the first connecting pads 126A.

The second pads 126_2 may be arranged in the first direction D1. The second pads 126_2 may be adjacent to the second side surface 120d of the first die 120.

In an embodiment, the first connecting wires 127 may be provided between the first pads 126_1 and the first connecting pads 126A. The first connecting wires 127 may be electrically connected with the first pads 126_1 and the first connecting pads 126A. For example, each of the first connecting wires 127 may extend from the first connecting pad 126A to the first pad 126_1 in the second direction D2.

Referring again to FIG. 3, in an embodiment, the through silicon vias 125 may include a first through silicon via 125_1 and a second through silicon via 125_2. For example, a lower surface of the first through silicon via 125_1 may be electrically connected with the first pad 126_1. For example, a lower surface of the second through silicon via 125_2 may be electrically connected with the second pad 126_2.

In an embodiment, the rear wires 144 may include a first rear wire 144_1. The first rear wire 144_1 may be electrically connected with the first through silicon via 125_1 and the second through silicon via 125_2. For example, the first pad 126_1 and the second pad 126_2 may be electrically connected through the first through silicon via 125_1, the first rear wire 144_1, and the second through silicon via 125_2. That is, an electrical signal received through the second pad 126_2 may be received to the first connecting pad 126A through the second through silicon via 125_2, the first rear wire 144_1, the first through silicon via 125_1, the first pad 126_1, and the first connecting wire 127.

Referring to FIG. 7 together, the rear wiring layer 140 and the second die 130 may be on the upper surface 120b of the first die 120.

The through silicon vias 125 may include the first through silicon vias 125_1 and the second through silicon vias 125_2. The first through silicon vias 125_1 may penetrate the first die 120 and may be electrically connected with the first pads 126_1, and the second through silicon vias 125_2 may penetrate the first die 120 and may be electrically connected with the second pads 126_2.

The rear wiring layer 140 may include the plurality of first rear wires 144_1. Each of the first rear wires 144_1 may be electrically connected with the first through silicon via 125_1 and the second through silicon via 125_2.

A first region RG1 and a second region RG2 may be defined on the upper surface 120b of the first die 120. The first region RG1 may be a region on which the second die 130 is positioned. The second region RG2 may be a region on which the second die 130 is not positioned.

In an embodiment, the second region RG2 may be adjacent to side surfaces of the first die 120. The first region RG1 may be spaced apart from the side surfaces of the first die 120. For example, the first region RG1 may be located on a central portion of the upper surface 120b of the first die 120, and the second region RG2 may be located on a peripheral portion of the upper surface 120b of the first die 120.

In an embodiment, the first rear wires 144_1 may be provided on the second region RG2. In other words, the first rear wires 144_1 may be provided on a region of the upper surface 120b of the first die 120 on which the second die 130 is not positioned. The first rear wires 144_1 may horizontally extend on the second region RG2 and may be electrically connected with the first through silicon vias 125_1 and the second through silicon vias 125_2.

In an embodiment of the present disclosure, connection to the first physical layer region PHY1 may be made through the second through silicon via 125_2, the first rear wire 144_1, the first through silicon via 125_1, the first pad 126_1, the first connecting wire 127, and the first connecting pad 126A. Accordingly, connection to the first physical layer region PHY1 and the second physical layer region PHY2 of the first die 120 may be made through the connecting pads 126_2 and 126B adjacent to the opposite side surfaces 120c and 120d of the first die 120.

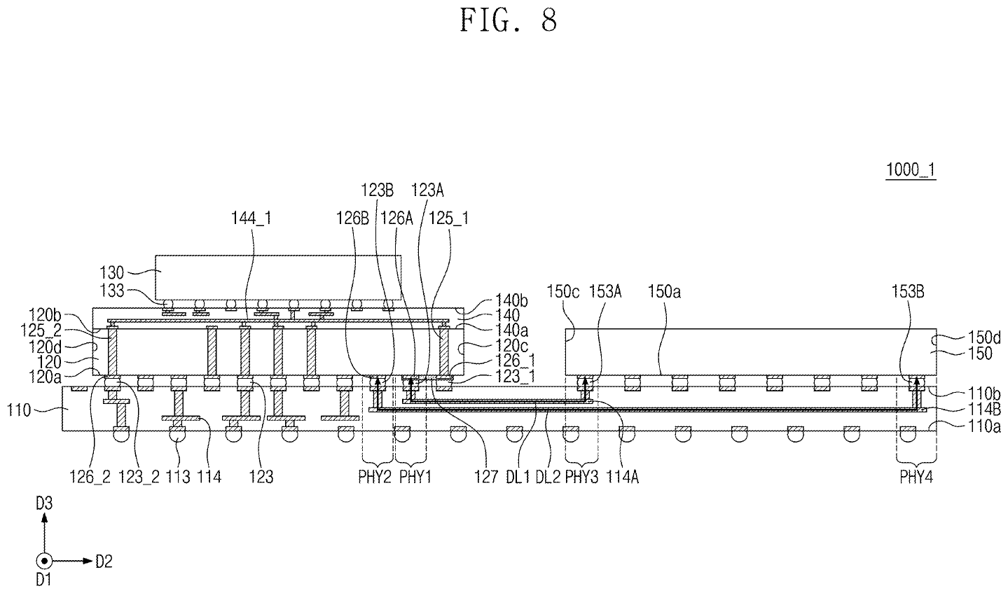

FIG. 8 is a view showing an example of a semiconductor package including the semiconductor device of FIG. 3. Hereinafter, description of the semiconductor device described above with reference to FIGS. 3 to 7 will be omitted.

Referring to FIG. 8, the semiconductor package 1000_1 may include the package substrate 110, the first die 120, the rear wiring layer 140, the second die 130, and a memory die 150. In an embodiment, in the semiconductor package 1000_1, the first die 120 and the memory die 150 may be arranged side by side on the package substrate 110.

The first die 120, the rear wiring layer 140, and the second die 130 on the package substrate 110 may be substantially the same as those illustrated in FIG. 3.

The memory die 150 may be provided on the package substrate 110. The memory die 150 may include a memory chip. For example, the memory chip may include DRAM, SRAM, MRAM, and/or NAND flash memory.

The memory die 150 may be spaced apart from the first die 120 on the upper surface 110b of the package substrate 110. For example, the memory die 150 may be spaced apart from the first side surface 120c of the first die 120 in the second direction D2.

Memory connecting terminals 153A, 153B may be provided on a lower surface 150a of the memory die 150. The memory connecting terminals 153A, 153B may be provided between the memory die 150 and the package substrate 110. The memory die 150 may be electrically connected with the package substrate 110 through the memory connecting terminals 153A, 153B.

The memory die 150 may include a third physical layer region PHY3 and a fourth physical layer region PHY4. A physical layer interface for connection to the memory die 150 may be provided in the third physical layer region PHY3 and the fourth physical layer region PHY4 of the memory die 150.

The third physical layer region PHY3 may be adjacent to a first side surface 150c of the memory die 150, and the fourth physical layer region PHY4 may be adjacent to a second side surface 150d of the memory die 150. The first side surface 150c and the second side surface 150d of the memory die 150 may face away from each other. For example, the first side surface 150c of the memory die 150 may face the first side surface 120c of the first die 120. In other words, the first side surface 150c of the memory die 150 may be adjacent to the first side surface 120c of the first die 120.

A first data line DL1 may be provided between the first physical layer region PHY1 and the third physical layer region PHY3. A second data line DL2 may be provided between the second physical layer region PHY2 and the fourth physical layer region PHY4. Data may be exchanged between the first die 120 and the memory die 150 through the first data line DL1 and the second data line DL2.

The memory connecting terminals 153 may include a first memory connecting terminal 153A electrically connected with the third physical layer region PHY3 of the memory die 150 and a second memory connecting terminal 153B electrically connected with the fourth physical layer region PHY4 of the memory die 150.

The package substrate 110 may include a plurality of conductive lines 114. The conductive lines 114 may include a first conductive line 114A and a second conductive line 114B. The first connecting terminal 123A and the first memory connecting terminal 153A may be electrically connected through the first conductive line 114A. The second connecting terminal 123B and the second memory connecting terminal 153B may be electrically connected through the second conductive line 114B.

The first connecting pad 126A, the first connecting terminal 123A, the first conductive line 114A, and the first memory connecting terminal 153A may constitute the first data line DL1. The first physical layer region PHY1 and the third physical layer region PHY3 may be electrically connected through the first data line DL1.

The second connecting pad 126B, the second connecting terminal 123B, the second conductive line 114B, and the second memory connecting terminal 153B may constitute the second data line DL2. The second physical layer region PHY2 and the fourth physical layer region PHY4 may be electrically connected through the second data line DL2.

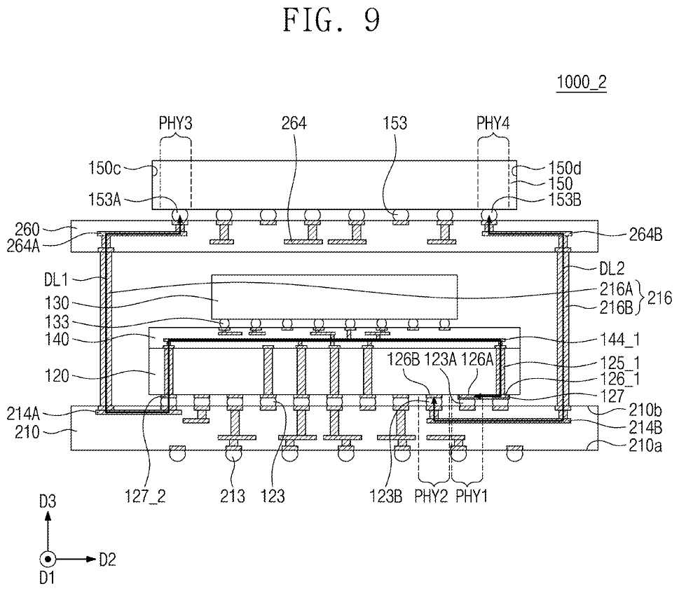

FIG. 9 is a view showing an example of a semiconductor package including the semiconductor device of FIG. 3. Hereinafter, description of the semiconductor device described above with reference to FIGS. 3 to 7 will be omitted.

Referring to FIG. 9, the semiconductor package 1000_2 may include a package substrate 210 having a lower surface 210a and an upper surface 210b, the first die 120, the rear wiring layer 140, the second die 130, and a memory die 150. In an embodiment, the semiconductor package 1000_2 may be a semiconductor package manufactured in a package-on-package (POP) form.

The first die 120, the rear wiring layer 140, and the second die 130 on the package substrate 210 may be substantially the same as those illustrated in FIG. 3.

An upper wiring layer 260 may be provided over the second die 130. Although not illustrated in FIG. 9, a molding film configured to cover the first die 120 and the second die 130 may be provided on an upper surface 210b of the package substrate 210, and the upper wiring layer 260 may be provided on the molding film.

The upper wiring layer 260 may include upper wires 264. The upper wires 264 may include a first upper wire 264A and a second upper wire 264B.

Conductive fillers 216 may be provided between the upper wiring layer 260 and the package substrate 210. The conductive fillers 216 may include a first conductive filler 216A and a second conductive filler 216B.

The conductive fillers 216 may be spaced apart from the first die 120. For example, the first conductive filler 216A may be spaced apart from the second side surface 120d of the first die 120 so as to be adjacent to the second side surface 120d, and the second conductive filler 216B may be spaced apart from the first side surface 120c of the first die 120 so as to be adjacent to the first side surface 120c. The first side surface 120c and the second side surface 120d of the first die 120 may face away from each other.

The upper wiring layer 260 and the package substrate 210 may be electrically connected through the conductive fillers 216. For example, the first conductive filler 216A may be electrically connected with the first upper wire 264A, and the second conductive filler 216B may be electrically connected with the second upper wire 264B.

The memory die 150 may be provided on the upper wiring layer 260. Memory connecting terminals 153 may be provided on a lower surface of the memory die 150. The memory connecting terminals 153 may be provided between the memory die 150 and the upper wiring layer 260. The memory die 150 may be electrically connected with the upper wiring layer 260 through the memory connecting terminals 153.

The first die 120 may include the first physical layer region PHY1 and the second physical layer region PHY2. A physical layer interface for connection to the first die 120 may be provided in the first physical layer region PHY1 and the second physical layer region PHY2 of the first die 120.

The memory die 150 may include a third physical layer region PHY3 and a fourth physical layer region PHY4. A physical layer interface for connection to the memory die 150 may be provided in the third physical layer region PHY3 and the fourth physical layer region PHY4 of the memory die 150.

The third physical layer region PHY3 may be adjacent to a first side surface 150c of the memory die 150, and the fourth physical layer region PHY4 may be adjacent to a second side surface 150d of the memory die 150. The first side surface 150c and the second side surface 150d of the memory die 150 may face away from each other.

A first data line DL1 may be provided between the first physical layer region PHY1 and the third physical layer region PHY3. A second data line DL2 may be provided between the second physical layer region PHY2 and the fourth physical layer region PHY4. Data may be exchanged between the first die 120 and the memory die 150 through the first data line DL1 and the second data line DL2.

The memory connecting terminals 153 may include a first memory connecting terminal 153A electrically connected with the third physical layer region PHY3 of the memory die 150 and a second memory connecting terminal 153B electrically connected with the fourth physical layer region PHY4 of the memory die 150.

The first memory connecting terminal 153A may be electrically connected with the first upper wire 264A. The second memory connecting terminal 153B may be electrically connected with the second upper wire 264B.

The package substrate 210 may include a plurality of conductive lines including a first conductive line 214A electrically connected with the second pad 126_2 and the first conductive filler 216A and a second conductive line 214B electrically connected with the second connecting terminal 123B and the second conductive filler 216B.

The first connecting pad 126A and the first memory connecting terminal 153A may be electrically connected through the first connecting wire 127, the first pad 126_1, the first through silicon via 125_1, the first rear wire 144_1, the second through silicon via 125_2, the second pad 126_2, the first conductive line 214A, the first conductive filler 216A, and the first upper wire 264A. The second connecting pad 126B and the second memory connecting terminal 153B may be electrically connected through the second connecting terminal 123B, the second conductive line 214B, the second conductive filler 216B, and the second upper wire 264B.

The first connecting pad 126A, the first connecting wire 127, the first pad 126_1, the first through silicon via 125_1, the first rear wire 144_1, the second through silicon via 125_2, the second pad 126_2, the first conductive line 214A, the first conductive filler 216A, the first upper wire 264A, and the first memory connecting terminal 153A may constitute the first data line DL1. The first physical layer region PHY1 and the third physical layer region PHY3 may be electrically connected through the first data line DL1.

The second connecting pad 126B, the second connecting terminal 123B, the second conductive line 214B, the second conductive filler 216B, the second upper wire 264B, and the second memory connecting terminal 153B may constitute the second data line DL2. The second physical layer region PHY2 and the fourth physical layer region PHY4 may be electrically connected through the second data line DL2.

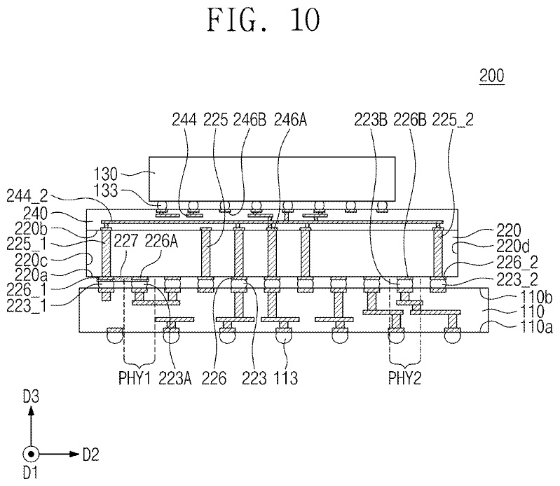

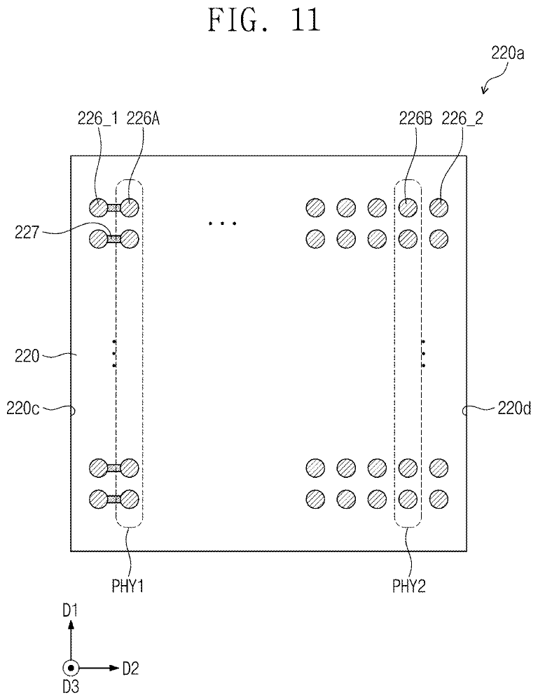

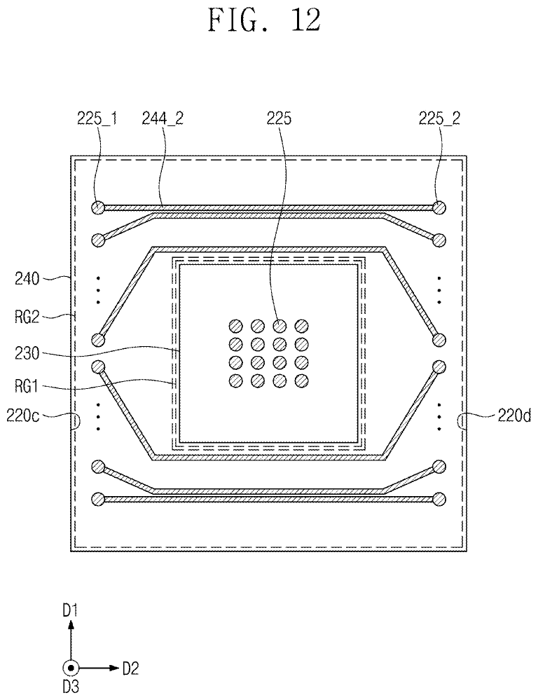

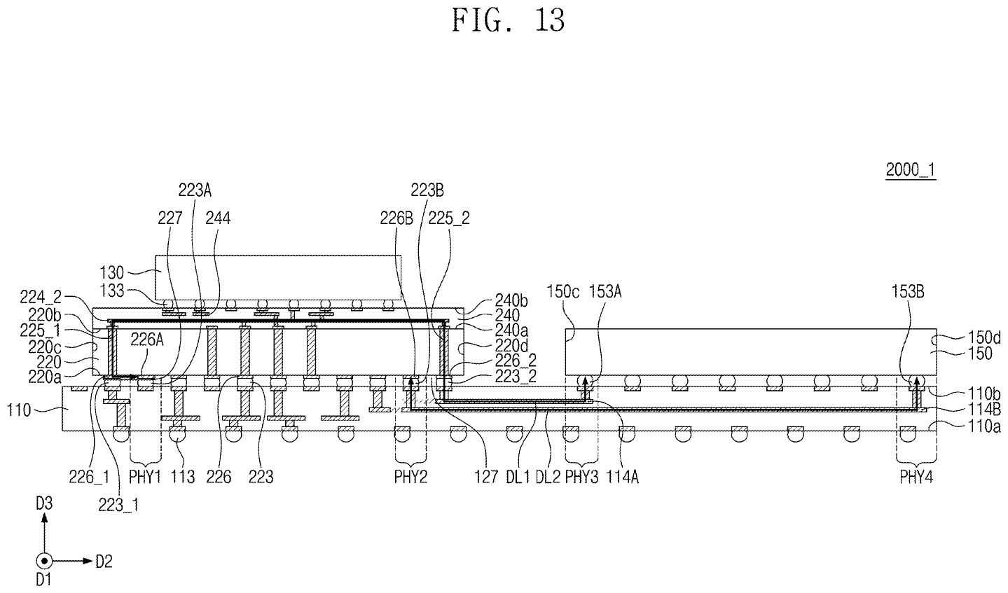

FIG. 10 is a view showing a semiconductor device according to an embodiment of the present disclosure. FIG. 11 is a view showing a lower surface of a first die of FIG. 10. FIG. 12 is a view showing the semiconductor device of FIG. 10 as viewed from above. Hereinafter, embodiments of the present disclosure will be described in detail with reference to FIGS. 10 to 12.

Referring to FIG. 10, the semiconductor device 200 may include a package substrate 110, the first die 220, a rear wiring layer 240, and a second die 130. For example, the semiconductor device 200 may be a 3D integrated circuit (3DIC).

The package substrate 110 may have a lower surface 110a parallel to the first direction D1 and the second direction D2 and an upper surface 110b facing away from the lower surface 110a. Solder balls 113 may be provided on the lower surface 110a of the package substrate 110.

The first die 220 may be provided on the upper surface 110b of the package substrate 110. The first die 220 may be a processor chip. For example, the first die 220 may include a central processing unit (CPU), a physical layer interface (PHY), and a memory controller (MCT).

The first die 220 may have the lower surface 220a and an upper surface 220b facing away from the lower surface 220a. The lower surface 220a of the first die 220 may face toward the package substrate 110.

Connecting pads 226 and connecting terminals 223 may be provided on the lower surface 220a of the first die 220. The connecting terminals 223 may be provided between the first die 220 and the package substrate 110. The connecting pads 226 may be provided between the connecting terminals 223 and the first die 220. The first die 220 may be electrically connected with the package substrate 110 through the connecting pads 226 and the connecting terminals 223.

The first die 220 may include a plurality of through silicon vias (TSVs) 225. The through silicon vias 225 may penetrate the first die 220. In other words, the through silicon vias 225 may extend from the lower surface 220a to the upper surface 220b of the first die 220 in the third direction D3 perpendicular to the lower surface 220a of the first die 220. The through silicon vias 225 may be electrically connected with some of the connecting pads 226.

The rear wiring layer 240 may be provided on the upper surface 220b of the first die 220. The rear wiring layer 240 may include first rear pads 246A, second rear pads 246B, and rear wires 244.

The first rear pads 246A may be provided on a lower surface of the rear wiring layer 240. The first rear pads 246A may be connected with the through silicon vias 215 on the upper surface 220b of the first die 220, respectively. The second rear pads 246B may be provided on an upper surface of the rear wiring layer 240. For example, the second rear pads 246B may be exposed on the upper surface of the rear wiring layer 240. The first rear pads 246A and the second rear pads 246B may be electrically connected through the rear wires 244.

The second die 130 may be provided on the upper surface of the rear wiring layer 240. Micro-bumps 133 may be provided between the second die 130 and the rear wiring layer 240. The second die 130 and the micro-bumps 133 may be substantially the same as those illustrated in FIG. 3.

The second die 130 may be electrically connected with the package substrate 110 through the micro-bumps 133, the second rear pads 246B, the rear wires 244, the first rear pads 246A, the through silicon vias 225, the connecting pads 226, and the connecting terminals 223.

The first die 220 may include a first physical layer region PHY1 and a second physical layer region PHY2. A physical layer interface for connection to the first die 220 may be provided in the first physical layer region PHY1 and the second physical layer region PHY2 of the first die 220.

In an embodiment, the first physical layer region PHY1 may be adjacent to a first side surface 220c of the first die 220, and the second physical layer region PHY2 may be adjacent to a second side surface 220d of the first die 220. The first side surface 220c and the second side surface 220d of the first die 220 may face away from each other.

The connecting pads 226 may include a first connecting pad 226A electrically connected with the first physical layer region PHY1 of the first die 220 and a second connecting pad 226B electrically connected with the second physical layer region PHY2 of the first die 220.

In an embodiment, the connecting pads 226 may include a first pad 226_1 and a second pad 226_2. For example, the first pad 226_1 may be adjacent to the first side surface 220c of the first die 220, and the second pad 226_2 may be adjacent to the second side surface 220d of the first die 220.

The connecting terminals 223 may include a first connecting terminal 223A electrically connected with the first connecting pad 226A and a second connecting terminal 223B electrically connected with the second connecting pad 226B.

In an embodiment, the connecting terminals 223 may include a first terminal 223_1 electrically connected with the first pad 226_1 and a second terminal 223_2 electrically connected with the second pad 226_2.

In an embodiment, a second connecting wire 227 may be provided on the lower surface 220a of the first die 220. The second connecting wire 227 may be electrically connected with the first connecting pad 226A and the first pad 226_1. In other words, the first pad 226_1 and the first connecting pad 226A may be electrically connected through the second connecting wire 227.

In embodiments, the second connecting wire 227 may be substantially the same as the first connecting wire 127 described above with reference to FIGS. 4 and 5.

Referring to FIG. 11 together, the connecting pads 226 may include the first connecting pads 226A connected to the first physical layer region PHY1 and the second connecting pads 226B connected to the second physical layer region PHY2.

The first connecting pads 226A connected with the first physical layer region PHY1 may be arranged in the first direction D1. In an embodiment, the second connecting pads 226B connected with the second physical layer region PHY2 may be arranged in the first direction D1. For example, the first connecting pads 226A may be adjacent to the second connecting pads 226B in the second direction D2.

In an embodiment, the connecting pads 226 may include the first pads 226_1 and the second pads 226_2.

The first pads 226_1 may be arranged in the first direction D1. For example, the first pads 226_1 may be adjacent to the first side surface 220c of the first die 220. For example, the first pads 226_1 may be adjacent to the first connecting pads 226A.

The second pads 226_2 may be arranged in the first direction D1. The second pads 226_2 may be adjacent to the second side surface 220d of the first die 220.

In an embodiment, the second connecting wires 227 may be provided between the first pads 226_1 and the first connecting pads 226A. The second connecting wires 227 may be electrically connected with the first pads 226_1 and the first connecting pads 226A. For example, each of the second connecting wires 227 may extend from the first connecting pad 226A to the first pad 226_1 in the second direction D2.

Referring again to FIG. 10, in an embodiment, the through silicon vias 225 may include a first through silicon via 225_1 and a second through silicon via 225_2. For example, a lower surface of the first through silicon via 225_1 may be electrically connected with the first pad 226_1. For example, a lower surface of the second through silicon via 225_2 may be electrically connected with the second pad 226_2.

In an embodiment, the rear wires 244 may include a second rear wire 244_2. The second rear wire 244_2 may be electrically connected with the first through silicon via 225_1 and the second through silicon via 225_2. For example, the first pad 226_1 and the second pad 226_2 may be electrically connected through the first through silicon via 225_1, the second rear wire 244_2, and the second through silicon via 225_2. That is, an electrical signal received through the second pad 226_2 may be received to the first connecting pad 226A through the second through silicon via 225_2, the second rear wire 244_2, the first through silicon via 225_1, the first pad 226_1, and the second connecting wire 227.

Referring to FIG. 12 together, the rear wiring layer 240 and the second die 130 may be on the upper surface 120b of the first die 220.

The through silicon vias 225 may include the first through silicon vias 225_1 and the second through silicon vias 225_2. The first through silicon vias 225_1 may penetrate the first die 220 and may be electrically connected with the first pads 226_1, and the second through silicon vias 225_2 may penetrate the first die 220 and may be electrically connected with the second pads 226_2.

The rear wiring layer 240 may include the plurality of second rear wires 244_2. The second rear wires 244_2 may be electrically connected with the first through silicon vias 225_1 and the second through silicon vias 225_2.

A first region RG1 and a second region RG2 may be defined on the upper surface 220b of the first die 220. The first region RG1 may be a region on which the second die 130 is positioned. The second region RG2 may be a region on which the second die 130 is not positioned.

In an embodiment, the second region RG2 may be adjacent to side surfaces of the first die 220. The first region RG1 may be spaced apart from the side surfaces of the first die 220. For example, the first region RG1 may be located on a central portion of the upper surface 220b of the first die 220, and the second region RG2 may be located on a peripheral portion of the upper surface 220b of the first die 220.

In an embodiment, the second rear wires 244_2 may be provided on the second region RG2. In other words, the second rear wires 244_2 may be provided on a region of the upper surface 220b of the first die 220 on which the second die 130 is not positioned. The second rear wires 244_2 may horizontally extend on the second region RG2 and may be electrically connected with the first through silicon vias 225_1 and the second through silicon vias 225_2.

In an embodiment of the present disclosure, connection to the first physical layer region PHY1 may be made through the second through silicon via 225_2, the second rear wire 244_2, the first through silicon via 225_1, the first pad 226_1, the second connecting wire 227, and the first connecting pad 226A. Accordingly, connection to the first physical layer region PHY1 and the second physical layer region PHY2 of the first die 220 may be made through the connecting pads 223B and 223_2 adjacent to one side surface of the first die 220.

FIG. 13 is a view showing an example of a semiconductor package including the semiconductor device of FIG. 10. Hereinafter, description of the semiconductor device described above with reference to FIGS. 10 to 12 will be omitted.

Referring to FIG. 13, the semiconductor package 2000_1 may include the package substrate 110, the first die 220, the rear wiring layer 240, the second die 130, and a memory die 150. In an embodiment, in the semiconductor package 2000_1, the first die 220 and the memory die 150 may be arranged side by side on the package substrate 110.

The first die 220, the rear wiring layer 240, and the second die 130 on the package substrate 110 may be substantially the same as those illustrated in FIG. 10.

The memory die 150 may be provided on the package substrate 110. Memory connecting terminals 153 may be provided on a lower surface of the memory die 150. The memory die 150 and the memory connecting terminals 153 may be substantially the same as those illustrated in FIG. 8.

The first die 220 may include the first physical layer region PHY1 and the second physical layer region PHY2. A physical layer interface for connection to the first die 220 may be provided in the first physical layer region PHY1 and the second physical layer region PHY2 of the first die 220.

The memory die 150 may include a third physical layer region PHY3 and a fourth physical layer region PHY4. A physical layer interface for connection to the memory die 150 may be provided in the third physical layer region PHY3 and the fourth physical layer region PHY4 of the memory die 150.

A first data line DL1 may be provided between the first physical layer region PHY1 and the third physical layer region PHY3. A second data line DL2 may be provided between the second physical layer region PHY2 and the fourth physical layer region PHY4. Data may be exchanged between the first die 220 and the memory die 150 through the first data line DL1 and the second data line DL2.

The first connecting pad 226A, the second connecting wire 227, the first pad 226_1, the first through silicon via 225_1, the second rear wire 244_2, the second through silicon via 225_2, the second pad 226_2, a first conductive line 114A, and a first memory connecting terminal 153A may constitute the first data line DL1. The first physical layer region PHY1 and the third physical layer region PHY3 may be electrically connected through the first data line DL1.

The second connecting pad 226B, the second connecting terminal 223B, a second conductive line 114B, and a second memory connecting terminal 153B may constitute the second data line DL2. The second physical layer region PHY2 and the fourth physical layer region PHY4 may be electrically connected through the second data line DL2.

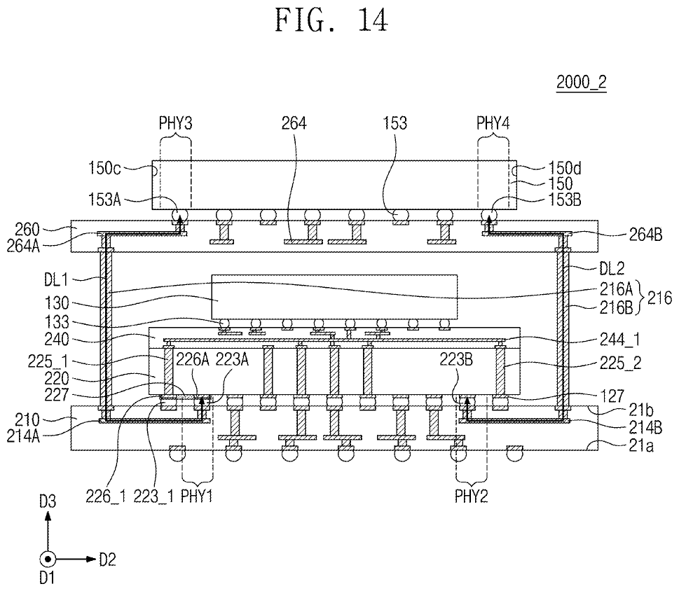

FIG. 14 is a view showing an example of a semiconductor package including the semiconductor device of FIG. 10. Hereinafter, description of the semiconductor device described above with reference to FIGS. 10 to 12 will be omitted.

Referring to FIG. 14, the semiconductor package 2000_2 may include a package substrate 210, the first die 220, the rear wiring layer 240, the second die 130, and a memory die 150. In an embodiment, the semiconductor package 2000_2 may be a semiconductor package manufactured in a package-on-package (POP) form.

The first die 220, the rear wiring layer 240, and the second die 130 on the package substrate 210 may be substantially the same as those illustrated in FIG. 3.

An upper wiring layer 260 may be provided over the second die 130. Conductive fillers 216A and 216B may be provided between the upper wiring layer 260 and the package substrate 210. The memory die 150 may be provided on the upper wiring layer 260. The upper wiring layer 260, the conductive fillers 216A and 216B, and the memory die 150 may be substantially the same as those illustrated in FIG. 2.

The first die 220 may include the first physical layer region PHY1 and the second physical layer region PHY2. A physical layer interface for connection to the first die 220 may be provided in the first physical layer region PHY1 and the second physical layer region PHY2 of the first die 220.

The memory die 150 may include a third physical layer region PHY3 and a fourth physical layer region PHY4. A physical layer interface for connection to the memory die 150 may be provided in the third physical layer region PHY3 and the fourth physical layer region PHY4 of the memory die 150.

A first data line DL1 may be provided between the first physical layer region PHY1 and the third physical layer region PHY3. A second data line DL2 may be provided between the second physical layer region PHY2 and the fourth physical layer region PHY4. Data may be exchanged between the first die 220 and the memory die 150 through the first data line DL1 and the second data line DL2.

The first connecting pad 226A and a first memory connecting terminal 153A may be electrically connected through the first connecting terminal 223A, the second connecting wire 227, a first conductive line 214A, the first conductive filler 216A, and a first upper wire 264A. The second connecting pad 226B and a second memory connecting terminal 153B may be electrically connected through the second connecting terminal 223B, a second conductive line 214B, the second conductive filler 216B, and a second upper wire 264B.

The first connecting pad 226A, the first connecting terminal 223A, the second connecting wire 227, the first conductive line 214A, the first conductive filler 216A, the first upper wire 264A, and the first memory connecting terminal 153A may constitute the first data line DL1. The first physical layer region PHY1 and the third physical layer region PHY3 may be electrically connected through the first data line DL1.

The second connecting pad 226B, the second connecting terminal 223B, the second conductive line 214B, the second conductive filler 216B, the second upper wire 264B, and the second memory connecting terminal 153B may constitute the second data line DL2. The second physical layer region PHY2 and the fourth physical layer region PHY4 may be electrically connected through the second data line DL2.

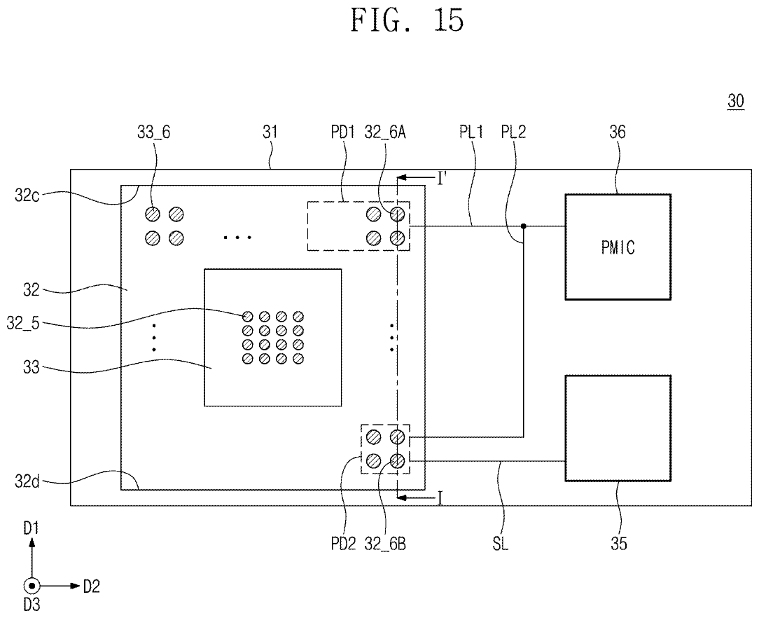

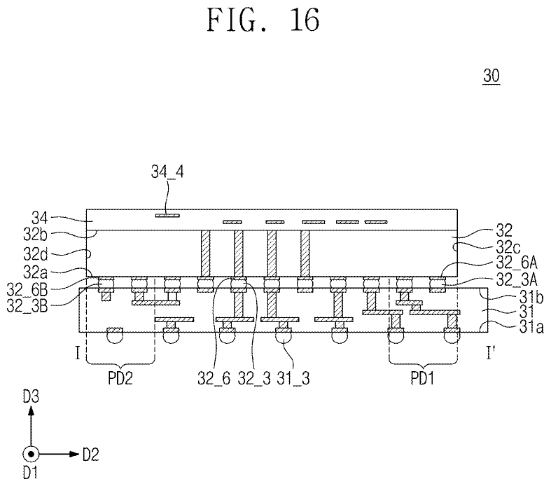

FIG. 15 is a view showing a semiconductor device. FIG. 16 is a sectional view taken along line I-I′ of FIG. 15.

Referring to FIGS. 15 and 16, the semiconductor device 30 may include a package substrate 31, a first die 32, a rear wiring layer 34, a second die 33, a power management IC (PMIC) 36, and a first semiconductor chip 35.

The package substrate 31 may include connecting pads 33_6, and have a lower surface 31a parallel to the first direction D1 and the second direction D2 and an upper surface 31b facing away from the lower surface 31a. The first direction D1 and the second direction D2 may be perpendicular to each other. Solder balls 31_3 may be provided on the lower surface 31a of the package substrate 31.

The first die 32 may be provided on the upper surface 31b of the package substrate 31. The first die 32 may be a processor chip. For example, the first die 32 may include a central processing unit (CPU), a physical layer interface (PHY), and a memory controller (MCT).

The first die 32 may have a lower surface 32a and an upper surface 32b facing away from the lower surface 32a. The lower surface 32a of the first die 32 may face toward the package substrate 31.

Connecting pads 32_6 and connecting terminals 32_3 may be provided on the lower surface 32a of the first die 32. The connecting terminals 32_3 may be provided between the first die 32 and the package substrate 31. The connecting pads 32_6 may be provided between the connecting terminals 32_3 and the first die 32. The first die 32 may be electrically connected with the package substrate 31 through the connecting pads 32_6 and the connecting terminals 32_3.

The first die 32 may include a plurality of through silicon vias (TSVs) 32_5. The through silicon vias 32_5 may penetrate the first die 32. In other words, the through silicon vias 32_5 may extend from the lower surface 32a to the upper surface 32b of the first die 32 in the third direction D3 perpendicular to the lower surface 32a of the first die 32. The through silicon vias 32_5 may be electrically connected with some of the connecting pads 32_6.

The rear wiring layer 34 may be provided on the upper surface 32b of the first die 32. The rear wiring layer 34 may include rear wires.

The second die 33 may be provided on an upper surface of the rear wiring layer 34. The second die 33 may be a processor chip. For example, the second die 33 may include a central processing unit (CPU), a graphic processing unit (GPU), or a system on chip (SoC). For example, the second die 33 may be a semiconductor chip of the same type as, or a different type from, the first die 32.

Micro-bumps may be provided between the second die 33 and the rear wiring layer 34. The second die 33 may be electrically connected with the package substrate 31 through the micro-bumps, the rear wires, the through silicon vias 32_5, the connecting pads 32_6, and the connecting terminals 32_3.

The first semiconductor chip 35 may be provided on the package substrate 31. In an embodiment, the first semiconductor chip 35 may be a memory chip. For example, the memory chip may include DRAM, SRAM, MRAM, and/or NAND flash memory. In an embodiment, the first semiconductor chip 35 may be a logic chip.

The first semiconductor chip 35 may be spaced apart from the first die 32 on the upper surface 31b of the package substrate 31. For example, the first semiconductor chip 35 may be spaced apart from one side surface of the first die 32 in the second direction D2.

The power management IC 36 may be provided on the package substrate 31. The power management IC 36 may be configured to generate a power voltage for driving the first die 32.

Power lines PL1 and PL2 may be provided on the package substrate 31. The power lines PL1 and PL2 may be electrically connected with the first die 32 and the power management IC 36. The power voltage may be provided from the power management IC 36 to the first die 32 through the power lines PL1 and PL2.

The power management IC 36 may be spaced apart from the first die 32 on the upper surface 31b of the package substrate 31. For example, the power management IC 36 may be spaced apart from the one side surface of the first die 32 in the second direction D2.

The first die 32 may include a first power domain PD1 and a second power domain PD2. An integrated circuit and/or electronic elements operating at the same power voltage may be provided in the first power domain PD1 and the second power domain PD2.

The first power domain PD1 may be adjacent to a first side surface 32c of the first die 32. The second power domain PD2 may be adjacent to a second side surface 32d of the first die 32. The first side surface 32c and the second side surface 32d may face away from each other.

The connecting pads 32_6 may include first connecting pads 32_6A electrically connected with the first power domain PD1 of the first die 32 and second connecting pads 32_6B electrically connected with the second power domain PD2 of the first die 32.

The connecting terminals 32_3 may include first connecting terminals 32_3A electrically connected with the first connecting pads 32_6A and second connecting terminal 32_3B electrically connected with the second connecting pads 32_6B.

A signal line SL may be provided on the package substrate 31. The signal line SL may include a plurality of signal lines SL. The signal line SL may be electrically connected with the first semiconductor chip 35 and some of the second connecting terminals 32_3B. For example, the second power domain PD2 of the first die 32 may exchange a signal with the first semiconductor chip 35 through the second connecting pad 32_6B, the second connecting terminal 32_3B, and the signal line SL.

The power lines PL1 and PL2 may include the first power line PL1 and the second power line PL2.

The first power line PL1 may be electrically connected with the power management IC 36 and some of the first connecting terminals 32_3A. The power voltage may be provided from the power management IC 36 to the first power domain PD1 through the first power line PL1, the first connecting terminal 32_3A, and the first connecting pad 32_6A.

The second power line PL2 may be electrically connected with the power management IC 36 and some of the second connecting terminals 32_3B. The power voltage may be provided from the power management IC 36 to the second power domain PD2 through the second power line PL2, the second connecting terminal 32_3B, and the second connecting pad 32_6B.

In the case of the semiconductor device of FIGS. 15 and 16, the first power domain PD1 and the second power domain PD2 that use the same power voltage may be adjacent to the opposite side surfaces 32c and 32d of the first die 32, respectively. Accordingly, the length of the second power line PL2 for supplying the power voltage from the power management IC 36 to the second power domain PD2 may be increased, and power stability may be deteriorated.

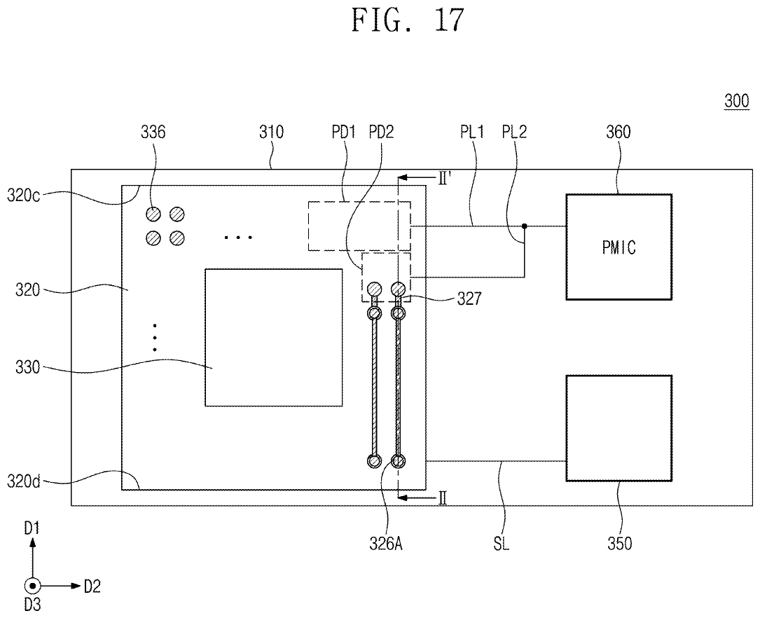

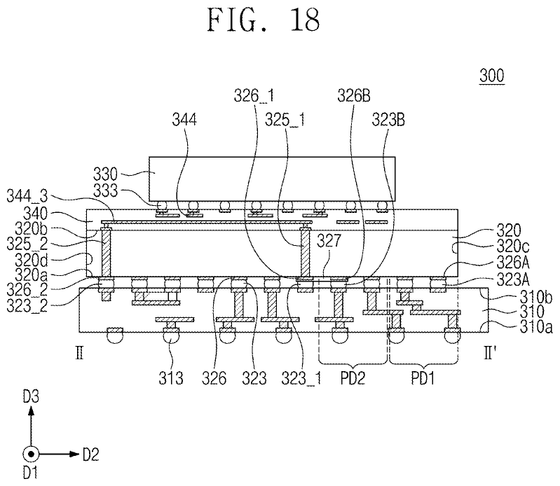

FIG. 17 is a view showing a semiconductor device according to an embodiment of the present disclosure. FIG. 18 is a sectional view taken along line II-II′ of FIG. 17. Hereinafter, embodiments of the present disclosure will be described in detail with reference to FIGS. 17 and 18.

Referring to FIGS. 17 and 18, the semiconductor device 300 may include a package substrate 310, a first die 320, a rear wiring layer 340, a second die 330, a power management IC 360, and a first semiconductor chip 350.

The package substrate 310 may have a lower surface 310a parallel to the first direction D1 and the second direction D2 and an upper surface 310b facing away from the lower surface 310a. The first direction D1 and the second direction D2 may be perpendicular to each other. Solder balls 313 may be provided on the lower surface 310a of the package substrate 310.

The first die 320 may be provided on the upper surface 310b of the package substrate 310. The first die 320 may be a processor chip.

The first die 320 may have a lower surface 320a and an upper surface 320b facing away from the lower surface 320a. The lower surface 320a of the first die 320 may face toward the package substrate 310.

Connecting pads 326, 336 and connecting terminals 323 may be provided on the lower surface 320a of the first die 320. The connecting terminals 323 may be provided between the first die 320 and the package substrate 310. The connecting pads 326 may be provided between the connecting terminals 323 and the first die 320. The first die 320 may be electrically connected with the package substrate 310 through the connecting pads 326, 336 and the connecting terminals 323.

The first die 320 may include a plurality of through silicon vias (TSVs) 325_1, 325_2. The through silicon vias 325_1, 325_2 may penetrate the first die 320. In other words, the through silicon vias 325 may extend from the lower surface 320a to the upper surface 320b of the first die 320 in the third direction D3 perpendicular to the lower surface 320a of the first die 320. The through silicon vias 325_1, 325_2 may be electrically connected with some of the connecting pads 326, 336.

The rear wiring layer 340 may be provided on the upper surface 320b of the first die 320. The rear wiring layer 340 may include rear wires 344.

The second die 330 may be provided on an upper surface of the rear wiring layer 340. The second die 330 may be a processor chip. For example, the second die 330 may include a central processing unit (CPU), a graphic processing unit (GPU), or a system on chip (SoC). For example, the second die 330 may be a semiconductor chip of the same type as, or a different type from, the first die 320.

Micro-bumps 333 may be provided between the second die 330 and the rear wiring layer 340. The second die 330 may be electrically connected with the package substrate 310 through the micro-bumps 333, the rear wires 344, the through silicon vias 325, the connecting pads 326, and the connecting terminals 323.

The first semiconductor chip 350 may be provided on the package substrate 310. In an embodiment, the first semiconductor chip 350 may be a memory chip. For example, the memory chip may include DRAM, SRAM, MRAM, and/or NAND flash memory. In an embodiment, the first semiconductor chip 350 may be a logic chip.

The first semiconductor chip 350 may be spaced apart from the first die 320 on the upper surface 310b of the package substrate 310. For example, the first semiconductor chip 350 may be spaced apart from one side surface of the first die 320 in the second direction D2.

The power management IC 360 may be provided on the package substrate 310. The power management IC 360 may be configured to generate a power voltage for driving the first die 320.

Power lines PL1 and PL2 may be provided on the package substrate 310. The power lines PL1 and PL2 may be electrically connected with the first die 320 and the power management IC 360. The power voltage may be provided from the power management IC 360 to the first die 320 through the power lines PL1 and PL2.

The power management IC 360 may be spaced apart from the first die 320 on the upper surface 310b of the package substrate 310. For example, the power management IC 360 may be spaced apart from the one side surface of the first die 320 in the second direction D2.

The first die 320 may include a first power domain PD1 and a second power domain PD2. An integrated circuit and/or electronic elements operating at the same power voltage may be provided in the first power domain PD1 and the second power domain PD2.

In an embodiment, the first power domain PD1 and the second power domain PD2 may be adjacent to each other. For example, the first power domain PD1 may be provided between the second power domain PD2 and a first side surface 320c.

The connecting pads 326 may include first connecting pads 326A electrically connected with the first power domain PD1 of the first die 320 and second connecting pads 326B electrically connected with the second power domain PD2 of the first die 320.

In an embodiment, the connecting pads 326 may include first pads 326_1 and second pads 326_2. For example, the first pads 326_1 may be adjacent to the second connecting pads 326B, and the second pads 326_2 may be adjacent to a second side surface 320d of the first die 320.

The connecting terminals 323 may include first connecting terminal 323A electrically connected with the first connecting pads 326A and second connecting terminal 323B electrically connected with the second connecting pads 326B.

In an embodiment, the connecting terminals 323 may include first terminals 323_1 electrically connected with the first pads 326_1 and second terminals 323_2 electrically connected with the second pads 326_2.

In an embodiment, third connecting wires 327 may be provided on the lower surface 320a of the first die 320. Each of the third connecting wires 327 may be electrically connected with the first connecting pad 326A and the first pad 326_1. In other words, the first pads 326_1 and the first connecting pads 326A may be electrically connected through the third connecting wires 327.

In an embodiment, the third connecting wire 327 may be substantially the same as the first connecting wire 127 described above with reference to FIGS. 4 and 5.

In an embodiment, the through silicon vias 325 may include first through silicon vias 325_1 and second through silicon vias 325_2. For example, a lower surface of each of the first through silicon vias 325_1 may be electrically connected with the first pad 326_1. For example, a lower surface of each of the second through silicon vias 325_2 may be electrically connected with the second pad 326_2.

In an embodiment, the rear wires 344 may include a third rear wire 344_3. The third rear wire 344_3 may be electrically connected with the first through silicon via 325_1 and the second through silicon via 325_2. For example, the first pad 326_1 and the second pad 326_2 may be electrically connected through the first through silicon via 325_1, the third rear wire 344_3, and the second through silicon via 325_2. That is, an electrical signal received through the second pad 326_2 may be received to the second connecting pad 326B through the second through silicon via 325_2, the third rear wire 344_3, the first through silicon via 325_1, the first pad 326_1, and the third connecting wire 327.

A signal line SL may be provided on the package substrate 310. The signal line SL may include a plurality of signal lines SL. The signal line SL may be electrically connected with the first semiconductor chip 350 and the second terminals 323_2. For example, the second power domain PD2 of the first die 320 may exchange a signal with the first semiconductor chip 350 through the second connecting pad 326B, the third connecting wire 327, the first through silicon via 325_1, the third rear wire 344_3, the second through silicon via 325_2, the second pad 326_2, the second terminal 323_2, and the signal line SL.

The power lines PL1 and PL2 may include the first power line PL1 and the second power line PL2.

The first power line PL1 may be electrically connected with the power management IC 360 and some of the first connecting terminals 323A. The power voltage may be provided from the power management IC 360 to the first power domain PD1 through the first power line PL1, the first connecting terminal 323A, and the first connecting pad 326A.

The second power line PL2 may be electrically connected with the power management IC 360 and some of the second connecting terminals 323B. The power voltage may be provided from the power management IC 360 to the second power domain PD2 through the second power line PL2, the second connecting terminal 323B, and the second connecting pad 326B.

In an embodiment of the present disclosure, connection to the second power domain PD2 may be made through the second through silicon via 325_2, the third rear wire 344_3, the first through silicon via 325_1, the first pad 326_1, the third connecting wire 327, and the second connecting pad 326B. Accordingly, in a floorplan step of designing the first die 320, the first power domain PD1 and the second power domain PD2 may be adjacent to each other, and power stability may be improved.

The embodiments of the present disclosure provide the semiconductor devices having improved electrical characteristics.

While the present disclosure has been described with reference to embodiments thereof, it will be apparent to those of ordinary skill in the art that various changes and modifications may be made thereto without departing from the spirit and scope of the present disclosure as set forth in the following claims.

Exemplary embodiments have been disclosed herein, and although specific terms are employed, they are used and are to be interpreted in a generic and descriptive sense only and not for purposes of limitation. Accordingly, it will be understood by those of ordinary skill in the art that various changes in form and details may be made without departing from the spirit and scope of the invention as set forth in the following claims.

What is claimed is:

1. A semiconductor device, comprising:
a first die including a first physical layer region and a second physical layer region adjacent to each other;
connecting pads on a lower surface of the first die;
a connecting wire on the lower surface of the first die;
a rear wiring layer on the first die, the rear wiring layer including a first rear wire; and
through silicon vias configured to penetrate the first die, the through silicon vias including a first through silicon via and a second through silicon via, the connecting pads having a first connecting pad electrically connected with the first physical layer region, a second connecting pad electrically connected with the second physical layer region, a first pad electrically connected with the first through silicon via, a second pad electrically connected with the second through silicon via, the first rear wire being electrically connected with the first through silicon via and the second through silicon via, the connecting wire being electrically connected with the first connecting pad and the first pad.

2. The semiconductor device as claimed in claim 1, wherein the first die includes a first side surface and a second side surface configured to face away from the first side surface, the first pad being adjacent to the first side surface, and the second pad being adjacent to the second side surface.

3. The semiconductor device as claimed in claim 1, wherein the first connecting pad and the first pad are adjacent to each other.

4. The semiconductor device as claimed in claim 1, wherein the connecting wire includes an under bump metal.

5. The semiconductor device as claimed in claim 3, wherein the connecting wire includes a redistribution layer.

6. The semiconductor device as claimed in claim 1, further comprising:
a second die on the rear wiring layer,
a first region and a second region defined on an upper surface of the first die, the first region being a region on which the second die is positioned, the second region being a region on which the second die is not positioned, the first rear wire being provided on the second region.

7. The semiconductor device as claimed in claim 6, wherein the first region is on a central portion of the upper surface of the first die.

8. The semiconductor device as claimed in claim 1, wherein the first die is a processor chip.

9. The semiconductor device as claimed in claim 1, further comprising connecting terminals on the connecting pads.

10. A semiconductor device, comprising:
a first die including a first physical layer region and a second physical layer region and including through silicon vias configured to penetrate the first die, the through silicon vias including a first through silicon via and a second through silicon via, the first physical layer region being adjacent to a first side surface of the first die, and the second physical layer region being adjacent to a second side surface configured to face away from the first side surface;
connecting pads on a lower surface of the first die, the connecting pads including a first connecting pad electrically connected with the first physical layer region, a second connecting pad electrically connected with the second physical layer region, a first pad electrically connected with the first through silicon via, and a second pad electrically connected with the second through silicon via;
a connecting wire on the lower surface of the first die, the connecting wire being electrically connected with the first connecting pad and the first pad; and
a rear wiring layer on the first die, the rear wiring layer including a second rear wire, the second rear wire being electrically connected with the first through silicon via and the second through silicon via.

11. The semiconductor device as claimed in claim 10, wherein the first pad is adjacent to the first side surface and the second pad is adjacent to the second side surface.

12. The semiconductor device as claimed in claim 10, wherein the first connecting pad and the first pad are adjacent to each other.

13. The semiconductor device as claimed in claim 10, wherein the connecting wire includes an under bump metal.

14. The semiconductor device as claimed in claim 13, wherein the connecting wire includes a redistribution layer.

15. A semiconductor device comprising:
a first die including a first power domain and a second power domain adjacent to each other, and having electronic elements configured to operate at a same power voltage provided in the first power domain and the second power domain, the first die including through silicon vias configured to penetrate the first die, the through silicon vias including a first through silicon via and a second through silicon via;
connecting pads on a lower surface of the first die, the connecting pads including a first connecting pad electrically connected with the first power domain, a second connecting pad electrically connected with the second power domain, a first pad electrically connected with the first through silicon via, and a second pad electrically connected with the second through silicon via;
a connecting wire on the lower surface of the first die, the connecting wire being electrically connected with the second connecting pad and the first pad; and
a rear wiring layer on the first die, the rear wiring layer including a third rear wire, the third rear wire being electrically connected with the first through silicon via and the second through silicon via.

16. The semiconductor device as claimed in claim 15, wherein the first die includes a first side surface and a second side surface configured to face away from the first side surface, the first power domain being adjacent to the first side surface, and the second pad being adjacent to the second side surface.

17. The semiconductor device as claimed in claim 16, wherein the second connecting pad and the first pad are adjacent to each other.

18. The semiconductor device as claimed in claim 15, wherein the connecting wire includes an under bump metal.

19. The semiconductor device as claimed in claim 15, wherein the connecting wire includes a redistribution layer.

20. The semiconductor device as claimed in claim 15, further comprising:
connecting terminals provided on the connecting pads.
